(19) United States
(12) Patent Application Publication
(10) Pub. No.: US 2024/0234129 A1
(43) Pub. Date: Jul. 11, 2024

(54) METHODS AND SYSTEMS FOR FORMING STRUCTURES COMPRISING A THRESHOLD VOLTAGE TUNING LAYER

(71) Applicant: ASM IP Holding B.V., Almere (NL)

(72) Inventors: Charles Dezelah, Helsinki (FI); Michael Eugene Givens, Oud-Heverlee (BE); Eric Jen Cheng Liu, Tempe, AZ (US); Eric James Shero, Phoenix, AZ (US); Fu Tang, Gilbert, AZ (US); Marko Tuominen, Helsinki (FI); Eva Elisabeth Tois, Espoo (FI); Andrea Illiberi, Leuven (BE); Tatiana Ivanova, Helsinki (FI); Paul Ma, Scottsdale, AZ (US); Gejian Zhao, Tempe, AZ (US)

(21) Appl. No.: 18/402,950

(22) Filed: Jan. 3, 2024

Related U.S. Application Data
(60) Provisional application No. 63/478,757, filed on Jan. 6, 2023.

(51) Int. Cl. H01L 21/02; H01L 21/311

(52) U.S. Cl. CPC H01L 21/02178; H01L 21/02208; H01L 21/0228; H01L 21/02312; H01L 21/31111

(57) ABSTRACT

Methods and systems for forming structure comprising a threshold voltage tuning layer are disclosed. Exemplary methods include providing a treatment reactant to a reaction chamber to form a treated surface on the substrate surface and depositing threshold voltage tuning material overlying the treated surface. Additionally or alternatively, exemplary methods can include direct formation of metal silicide layers. Additionally or alternatively, exemplary methods can include use of an etchant.

### CROSS-REFERENCE TO RELATED APPLICATIONS

This application is a nonprovisional of, and claims priority to and the benefit of, U.S. Provisional Patent Application No. 63/478,757, filed Jan. 6, 2023 and entitled “METHODS AND SYSTEMS FOR FORMING STRUCTURES COMPRISING A THRESHOLD VOLTAGE TUNING LAYER,” which is hereby incorporated by reference herein.

### FIELD OF DISCLOSURE

The present disclosure generally relates to the field of semiconductor processing methods and systems. More particularly, the disclosure relates to methods and systems for forming structures that include a threshold voltage tuning layer.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes.

For example, one challenge has been finding a suitable conducting material for use as a gate electrode in aggressively scaled CMOS devices. Various gate materials might be used, such as, for example, a metal, such as a titanium nitride layer. However, in some cases, where higher work function values than those obtained with titanium nitride layers—e.g., in PMOS regions of a CMOS device—are desired, improved materials for gate electrodes are desired. Such materials can include relatively thin layers of threshold voltage tuning material to form n- or p-dipole shifting regions.

While such threshold voltage tuning layers can work for a variety of applications, a desired thickness of a threshold voltage tuning layer can be difficult to control. In particular, a first few deposition cycles or an initial thickness of the threshold voltage tuning layer can be relatively high and difficult to control, compared to subsequent cycles or bulk deposition of the threshold voltage tuning layer. Accordingly, especially as critical dimensions of devices continue to decrease, improved methods and systems for forming threshold voltage tuning layers are desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of forming a structure comprising a threshold voltage tuning layer, to structures and devices formed using such methods, and to systems for performing the methods and/or for forming the structures and/or devices. The structures can be used in the formation of a variety of devices that are suitable for a variety of applications. For example, the structures can be used in the formation of a gate electrode in n- or p-channel metal oxide semiconductor field effect transistors (MOSFETS).

In accordance with various examples of the disclosure, a method of forming a structure comprising a threshold voltage tuning layer is provided. As set forth in more detail below, exemplary methods can include treating a surface of a substrate to control a deposition rate of a subsequently deposited threshold voltage shifting layer.

In accordance with embodiments of the disclosure, a method of forming a structure comprising a threshold voltage tuning layer includes providing a substrate comprising a substrate surface within a reaction chamber, providing a treatment reactant comprising a metal treatment precursor to the reaction chamber to form a treated surface on the substrate surface, and depositing threshold voltage tuning material overlying the treated surface. The treatment reactant can inhibit deposition of the threshold voltage tuning material, such that a desired (e.g., relatively low, controlled) growth rate can be achieved. In accordance with various aspects of these embodiments, the metal treatment precursor comprises a metal selected from one or more of hafnium or zirconium. In at least some cases, the substrate surface can include the metal. In accordance with further examples of these embodiments, the step of depositing threshold voltage tuning material comprises a cyclical deposition process. The cyclical process can include, for example, providing a threshold voltage tuning material precursor to the reaction chamber and providing a threshold voltage tuning material reactant to the reaction chamber. In accordance with further examples, the threshold voltage tuning material reactant can remove a ligand of the treatment reactant on the treated surface.

In accordance with further embodiments of the disclosure, a method of forming a structure comprising a threshold voltage tuning layer includes providing a substrate comprising a substrate surface within a reaction chamber, providing a treatment reactant comprising a carbon-containing treatment precursor to the reaction chamber to form a treated surface on the substrate surface, and depositing threshold voltage tuning material overlying the treated surface. In accordance with examples of these embodiments, the carbon-containing treatment precursor comprises one or more of an aminosilane, an alkyl amine, and formamidine. In accordance with further examples, the carbon-containing treatment precursor comprises one or more of an acyl halide or an alkyl diacyl halide. In accordance with yet further examples, the carbon-containing treatment precursor comprises a carboxylic acid anhydride. In accordance with yet further examples, the carbon-containing treatment precursor comprises an alcohol.

In accordance with yet further examples of the disclosure, a method of forming a structure comprising a threshold voltage tuning layer includes providing a substrate comprising a substrate surface within a reaction chamber and using a cyclical deposition process, depositing threshold voltage tuning material overlying the substrate surface. The method can optionally include a treatment step, such as a treatment step described above and elsewhere herein. The cyclical deposition process can include providing a metal deposition precursor to the reaction chamber, providing a silicon precursor to the reaction chamber, and providing an oxidant to the reaction chamber. For example, the cyclical deposition process can include providing the silicon precursor to the reaction chamber, providing the oxidant to the reaction chamber, providing the metal deposition precursor to the reaction chamber and providing the oxidant or another oxidant to the reaction chamber. These steps can be repeated to form a desired thickness of the threshold voltage tuning layer. In accordance with some aspects of these embodiments, the step of providing the silicon precursor may be the first step in the cyclical deposition process. In accordance with further aspects, the step of providing the metal deposition precursor comprises providing a carbon-free, halogen-containing metal precursor. In accordance with yet further aspects, the step of providing the silicon precursor comprises providing a carbon-free, halogen-containing silicon precursor. In accordance with additional aspects, the threshold voltage tuning layer comprises one or more of silicon-doped niobium oxide and silicon-doped aluminum oxide.

In accordance with yet further examples of the disclosure, a method of forming a structure comprising a threshold voltage tuning layer includes providing a substrate comprising a substrate surface within a reaction chamber, depositing threshold voltage tuning material overlying the substrate surface, and providing an etchant to the reaction chamber. The etchant can be used to mitigate growth and/or reduce a thickness of the threshold voltage tuning material. The method can further include forming a metal oxide layer over a threshold voltage tuning layer. The etchant can be or include a neutral compound that is capable of forming volatile complexes of a metal of the threshold voltage tuning layer. Exemplary etchants include beta-diketonate compounds, such as H(acac).

Further described herein is a system comprising a reaction chamber, a treatment reactant source, a threshold voltage tuning material precursor, a threshold voltage tuning material reactant, and a controller. The controller is configured to control gas flow into the reaction chamber to form a threshold voltage tuning layer by means of a method as described herein.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIG. 2 illustrates another method in accordance with exemplary embodiments of the disclosure.

FIG. 3 illustrates yet another method in accordance with additional examples of the disclosure.

FIGS. 4-7 illustrate structures in accordance with examples of the disclosure.

FIG. 8 illustrates a treatment mechanism in accordance with examples of the disclosure.

FIG. 9 illustrates a system in accordance with yet additional exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various examples are set forth as exemplary embodiments. Unless otherwise noted, the examples or components thereof may be combined or may be applied separate from each other.

As set forth in more detail below, various embodiments of the disclosure provide methods for forming structures including a threshold voltage tuning layer. The structures can be suitable for use as, for example, gate electrode structures. Exemplary methods can be used to, for example, form CMOS devices, or portions of such devices. This notwithstanding, and unless noted otherwise, the invention is not necessarily limited to such examples.

In this disclosure, gas can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term precursor can refer to a compound that participates in the chemical reaction that produces another compound, and particularly to a compound that constitutes a film matrix or a main skeleton of a film. The term reactant can be used to refer to a gas that reacts with the precursor to form deposited material. In some cases, the term reactant can be used interchangeably with the term precursor.

As used herein, the term substrate can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material or high k dielectric material is material having a dielectric constant greater than the dielectric constant of silicon dioxide.

As used herein, the term film and/or layer can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may comprise material or a layer with pinholes and/or isolated islands. A film or layer may be at least partially continuous. A film or layer may be patterned, e.g., subdivided, and may be comprised in a plurality of semiconductor devices.

As used herein, a structure can be or include a substrate as described herein. Structures can include one or more layers overlying the substrate, such as one or more layers formed according to a method as described herein. Device portions can be or include structures.

The term deposition process as used herein can refer to the introduction of precursors (and/or reactants) into a reaction chamber to deposit a layer or material over a substrate. Cyclical deposition processes are examples of deposition processes.

The term cyclic deposition process or cyclical deposition process can refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component.

As used herein, the term purge can refer to a procedure in which an inert or substantially inert gas is provided to a reaction chamber in between two pulses of gases that might otherwise react with each other. For example, a purge, e.g., using a an inert gas, such as a noble gas, may be provided between a precursor pulse and a reactant pulse to reduce gas phase interactions between the precursor and the reactant that might otherwise occur. It shall be understood that a purge can be effected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

Further, in this disclosure, any two numbers of a variable can constitute a workable range of the variable, and any ranges indicated may include or exclude the endpoints. Additionally, any values of variables indicated (regardless of whether they are indicated with the term about or not) may refer to precise values or approximate values and include equivalents, and may refer to average, median, representative, majority, or the like. Further, in this disclosure, the terms including, constituted by and having refer independently to typically or broadly comprising, comprising, consisting essentially of, or consisting of in some embodiments.

In this disclosure, any defined meanings do not necessarily exclude ordinary and customary meanings, in some embodiments.

Described herein are methods of forming a structure including a threshold voltage tuning layer. As set forth in more detail below, exemplary methods provide techniques for providing desired growth rate and/or other properties of a deposited threshold voltage tuning layer. The layers formed according to the present methods are highly advantageous, e.g., for the purpose of work function tuning, stress management, and/or resistivity tuning.

Layers formed using a presently described method may be useful, for example, as gate stack work function tuning metals in P- or N-MOSFETS. Additionally or alternatively, the threshold voltage tuning layers may be used in MIM metal electrodes and/or in VNAND contacts.

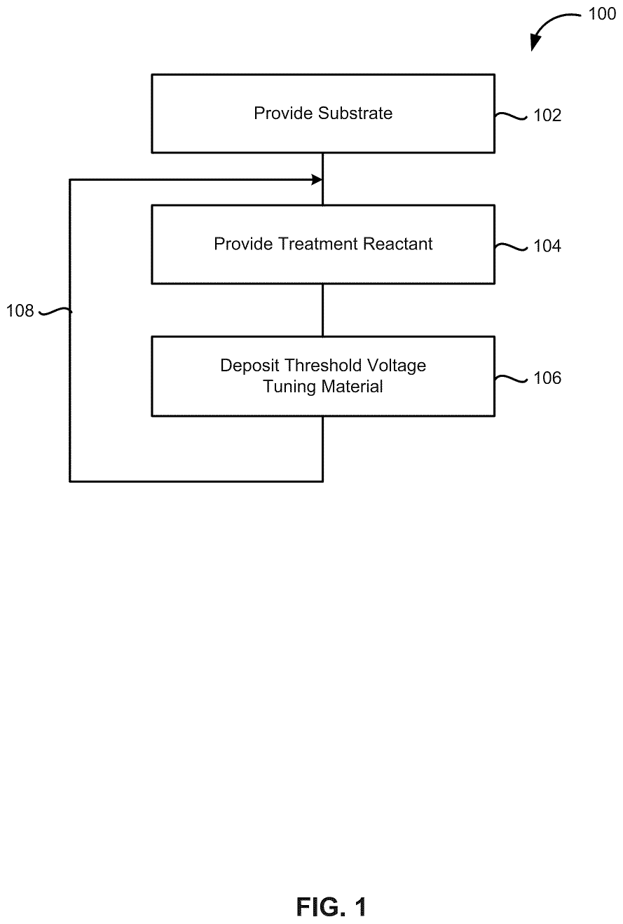

Turning now to the figures, FIG. 1 illustrates an exemplary method 100 in accordance with embodiments of the disclosure. As illustrated, method 100 includes the steps of providing a substrate (102), providing a treatment reactant (104), and depositing threshold voltage tuning material (106). Although not separately illustrated, method 100 can include a drive-in anneal in some cases.

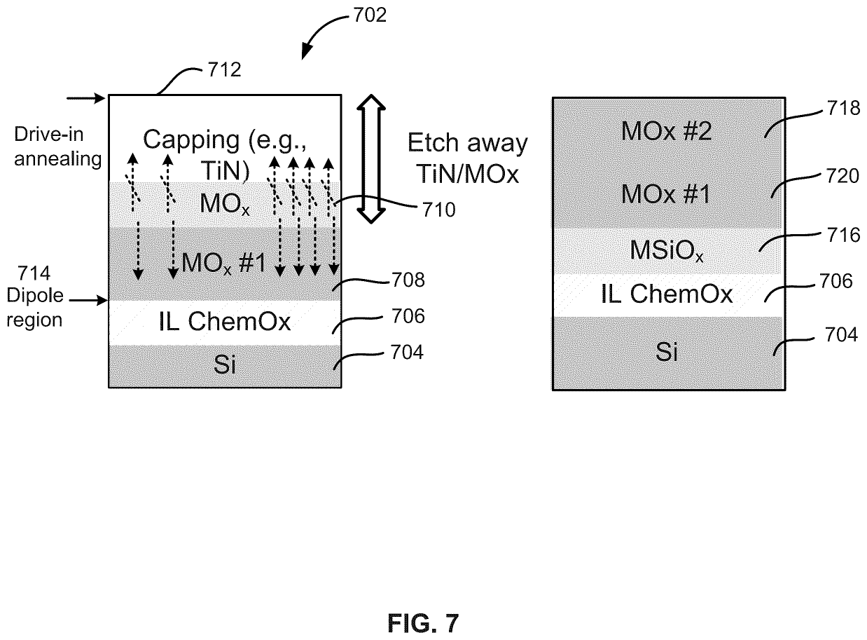

Method 100 and other methods described herein can be used to form dipole first structures, in which the threshold voltage tuning layer is formed directly on an interlayer dielectric or a silicon oxide or a treated surface thereof, or dipole last, in which the threshold voltage tuning layer is formed directly on a high-k dielectric layer or treated surface thereof, or dipole middle, which is illustrated in FIG. 7.

As illustrated in FIG. 7, an intermediate structure 702 can be formed by forming a threshold voltage tuning material layer 710 overlying a first high-k dielectric material layer 708, an interlayer dielectric (e.g., silicon oxide) layer 706, and a substrate 704. A capping layer 712 (e.g., titanium nitride) can be used during a drive-in anneal step to form a dipole region 714 and ultimately metal silicate region 716. Capping layer 712 and remaining voltage tuning material layer 710 can be removed and a second high-k dielectric material 718 can be formed overlying remaining first high-k dielectric material 720.

Referring again to FIG. 1, during step 102, a substrate is provided within a reaction chamber. The reaction chamber used during step 102 can be or include a reaction chamber of a chemical vapor deposition reactor system configured to perform a cyclical deposition process. The reaction chamber can be a standalone reaction chamber or part of a cluster tool.

In accordance with examples of the disclosure, the substrate can comprise a surface comprising an oxide. The oxide can be, for example, a (e.g., deposited) silicon oxide or a metal oxide, such as a high dielectric constant metal oxide, such as hafnium oxide, zirconium oxide, hafnium zirconium oxide, hafnium silicate, or the like.

Step 102 can include heating the substrate to a desired deposition temperature within the reaction chamber. In some embodiments of the disclosure, step 102 includes heating the substrate to a temperature of less than 100° C. For example, in some embodiments of the disclosure, heating the substrate to a deposition temperature may comprise heating the substrate to a temperature between approximately 20° C. and approximately 100° C., about 200° C. and about 300° C., about 20° C. and about 400° C., or about 20° C. and about 600° C.

In addition to controlling the temperature of the substrate, a pressure within the reaction chamber may also be regulated. For example, in some embodiments of the disclosure, the pressure within the reaction chamber during step 102 may be less than 760 Torr or between 0.2 Torr and 760 Torr, about 1 Torr and 100 Torr, or about 1 Torr and 10 Torr.

During step 104, a treatment reactant is provided to the reaction chamber to form a treated surface on the substrate surface. In accordance with examples of the disclosure, the treatment reactant can be used to control (e.g., inhibit) deposition of the threshold voltage tuning material.

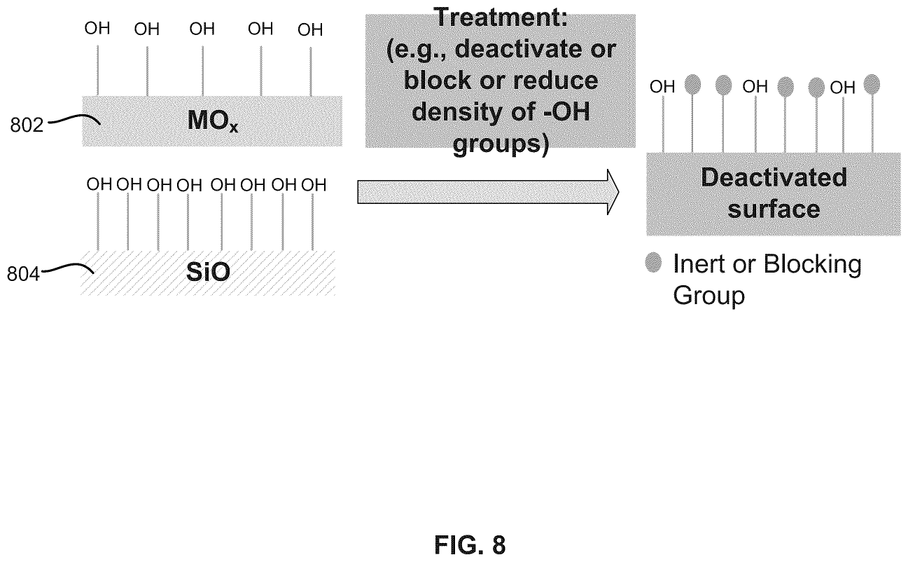

FIG. 8 illustrates a possible mechanism for step 104. A substrate 802, including a metal oxide surface, or a substrate 804, including a silicon oxide surface, can include a plurality of active sites, such as —OH terminated sites. During step 104, at least some of the otherwise active sites can be deactivated and/or blocked with inert and/or blocking groups using methods described herein.

In accordance with examples of the disclosure, the treatment reactant comprises a metal treatment precursor. The metal precursor can include, for example, one or more of hafnium, zirconium, aluminum, or the like. For example, in cases in which the substrate comprises a metal oxide (MOₓ), the metal precursor can include the same metal (M). By way of particular examples, the metal treatment precursor can include one or more of a hafnium halide, such as hafnium chloride (HfCl₄), tetrakis(ethylmethylamido)hafnium(TEMAHf), bis(methylcyclopentadienyl) methylmethoxy Hf, zirconium chloride (ZrCl₄), tetrakis(ethylmethylamido)zirconium(TEMAZr), bis(methylcyclopentadienyl) methylmethoxy Zr, tris (dimethylamino) (cyclopentadienyl)zirconium, or the like. The metal precursor is thought to occupy otherwise reactive sites during step 106.

During step 106, a threshold voltage tuning material is deposited overlying the treated surface. In accordance with examples of these embodiments, step 106 includes a cyclical process. The cyclical process can include providing a threshold voltage tuning material precursor to the reaction chamber and providing a threshold voltage tuning material reactant to the reaction chamber.

Exemplary threshold voltage tuning material precursors suitable for use with step 106 include metal-containing precursors, such as precursors comprising one or more of lanthanum, aluminum, zinc or the like. Particular threshold voltage tuning material precursors include trimethylaluminum (TMA), diethylzinc (DeZn), tris(dimethylamido) gallium, lanthanum formamidinate (La(fAMD)₃), tris(N,N′-diisopropylacetamidinato)lanthanum (La(iPrAMD)₃), a diketonate precursor, such as (La(THD)₃); a Cp(cyclopentadienyl)-based precursor such as tris(isopropyl-cyclopentadienyl)lanthanum (La(iPrCp)₃); or an amido-based chemistry such as tris(bistrimethylsilylamido)-lanthanum (La[N(SiMe₃)₂]₃), or hybrid combinations of the above, and the like. A flowrate of the threshold voltage tuning material precursor to the reaction chamber can be between about 1 and about 20 sccm. A duration of a pulse of the threshold voltage tuning material precursor to the reaction chamber can be between about 0.1 second and about 20 seconds.

Exemplary threshold voltage tuning material reactants suitable for use with step 106 include oxidants, such as H₂O, ozone, H₂O₂, or other reactants, such as NH₃, hydrazine, and the like. A flowrate of the threshold voltage tuning material reactant to the reaction chamber can be between about 10 and about 5000 sccm. A duration of a pulse of threshold voltage tuning material reactants to the reaction chamber can be between about 0.05 seconds and about 2 seconds or can be continuous through one or more deposition cycles and/or through one or more of cycles (108) of steps 104 and 106.

During the step of providing the threshold voltage tuning material reactant, a ligand of the treatment reactant on the treated surface can be removed, thereby removing any (e.g., carbon) contaminants that might otherwise remain.

As illustrated in FIG. 1, steps 104 and 106 can be repeated (108)—e.g., to form a desired thickness of the threshold voltage tuning material. In such cases, step 104 can be used to refresh a surface of a substrate prior to deposition of the threshold voltage tuning material. Additionally or alternatively, step 104 can be repeated a number of times prior to proceeding to step 106. In some cases, steps 104 and 106 can be repeated a number of times and then 106 alone can be repeated to form the threshold voltage tuning material of a desired thickness. For example, steps 104 and 106 can be repeated about 1 or 0 to about 5 or about 1 to about 10 times and then step 106 can be repeated about 1 or 0 to about 5 or about 1 to about 10 times.

In some embodiments, subsequent deposition cycles are separated by an inter-deposition cycle purge. In some embodiments, the duration of the inter-deposition cycle purge is from at least 0.025 s to at most 2.0 s, or from at least 0.05 s to at most 0.8 s, or from at least 0.1 s to at most 0.4 s, or from at least 0.2 s to at most 0.3 s.

In some embodiments, a threshold voltage tuning material precursor pulse and a threshold voltage tuning material reactant pulse are separated by an intra deposition cycle purge. In some embodiments, the duration of the intra deposition cycle purge is from at least 0.025 s to at most 2.0 s, or from at least 0.05 s to at most 0.8 s, or from at least 0.1 s to at most 0.4 s, or from at least 0.2 s to at most 0.3 s.

In accordance with additional examples of method 100, step 104 can additionally or alternatively include providing a treatment reactant comprising a carbon-containing treatment precursor to the reaction chamber to form a treated surface on the substrate surface. In these cases, a carbon functional group can form on the treated surface to provide a more inert or less reactive site for a subsequently provided voltage tuning material precursor that is provided during step 106. For example, the carbon functional group may be more hydrophobic than an untreated surface. In these cases, steps 102 and 106 can be as described above.

Exemplary carbon-containing treatment precursors can include amine or amine derivatives. For example, the carbon-containing treatment precursor can include one or more of an aminosilane (e.g., bis(N, N dimethylamino)dimethylsilane (DMADMS), (N, N dimethylamino)trimethylsilane (DMATMS), or the like), an alkyl amine (e.g., trimethylamine or other C1-C4 substituted amine), and formamidine. The aminosilane can replace —OH on the substrate surface with —Si—CH₃ group, which is less reactive and more hydrophobic than —OH, and leave SiO₂ after ligand and residue burn off (e.g., during provision of an oxidant during step 106). The alkyl amine can replace —OH on the substrate surface with —N—CH₃; any carbon residue can be burned off completely during step 106. The formamidine can replace —OH on the substrate surface with a ligand similar to a threshold voltage tuning material precursor ligand and can block the adsorption of the threshold voltage tuning material precursor; the residue can be burned off during step 106.

In accordance with additional examples, the carbon-containing treatment precursor can include one or more of an acyl halide (e.g., a C1-C4 acyl halide), where the halide can be, for example, C1 (e.g., acylchloride) or an (e.g., C1-C4) alkyl diacyl halide (e.g., adipoyl chloride). In these cases, the treatment reactant can provide (e.g., —COCl) functional groups in place of —OH groups on the substrate surface, releasing (e.g., HCl) and occupying a reactive site. The halogen may further hinder growth to some extent. Thus, the chemisorbed molecules will hinder the chemisorption of the threshold voltage tuning material precursor during step 106, slowing down the growth per cycle for the threshold voltage tuning material. The surface can be re-activated by using an oxidant (e.g., ozone) pulse (e.g., during step 106), thereby burning the carbon from the chemisorbed molecules and restoring the —OH terminal groups. Residual halogen can be removed using during the step of providing an oxidant, wherein, for example, H₂O is a reactant and/or byproduct.

In accordance with yet further examples of the disclosure, the carbon-containing treatment precursor can include one or more (e.g., C2-C16, C2-C12, or C2-C6) carboxylic acid anhydrides, such as acetic anhydride, succinic anhydride, maleic anhydride, formic anhydride, proponolic anhydride, butyric anhydride, isobutyric anhydride), halogen substituted—e.g., on terminal end groups or elsewhere-variants thereof, valeric anhydride, crotonic anhydride, or hexanoic anhydride. It is thought that the carboxylic acid anhydrides will displace many of the —H on the —OH groups on the substrate surface with a less reactive acetate group which will reduce chemisorption of threshold voltage tuning material precursor, resulting in a suppressed growth per cycle (GPC) closer to a bulk GPC of the threshold voltage tuning layer. The acetate groups can be displaced upon first providing a threshold voltage tuning material reactant, recovering the surface termination on voltage tuning material layer after a first cycle. Subsequent voltage tuning material deposition steps can exhibit typical (e.g., bulk) GPC. The surface can be refreshed as noted above by providing an oxidant, such as ozone—e.g., during a deposition cycle to form the threshold voltage tuning material.

In accordance with yet further examples of these embodiments, the carbon-containing treatment precursor can include one or more (e.g., C1-C12, C1-C6 or C1-C3 linear or branched) alcohols, such as, for example, methanol, ethalnol, isopropynol, n-propynol, 1 butynol, 2 butynol, iso but, or tert butynol. The substrate surface can be refreshed and/or carbon residue can be removed as noted above by providing an oxidant, such as ozone—e.g., during a deposition cycle to form the threshold voltage tuning material.

As above, steps 104 and 106 can be repeated a desired number of times (e.g., until a desired GPC is obtained) and then step 106 can be repeated until a desired thickness of the threshold voltage tuning layer is obtained.

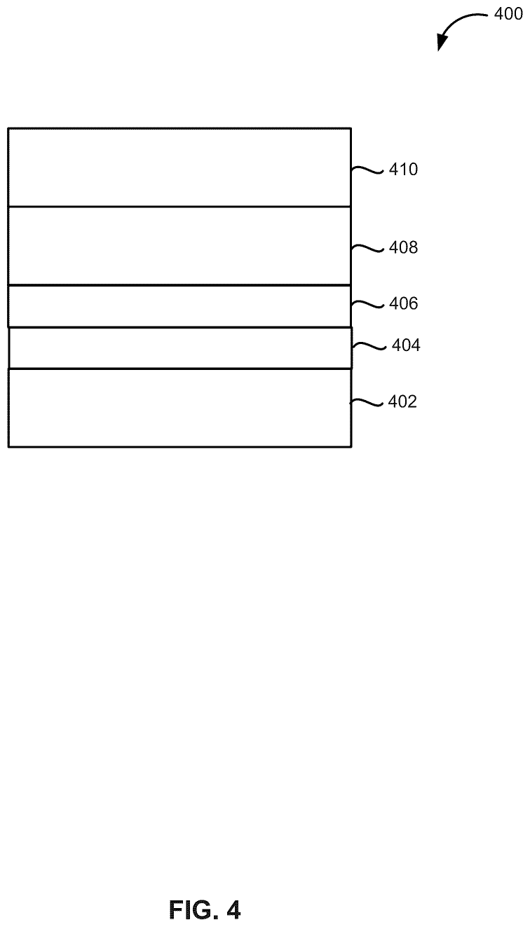

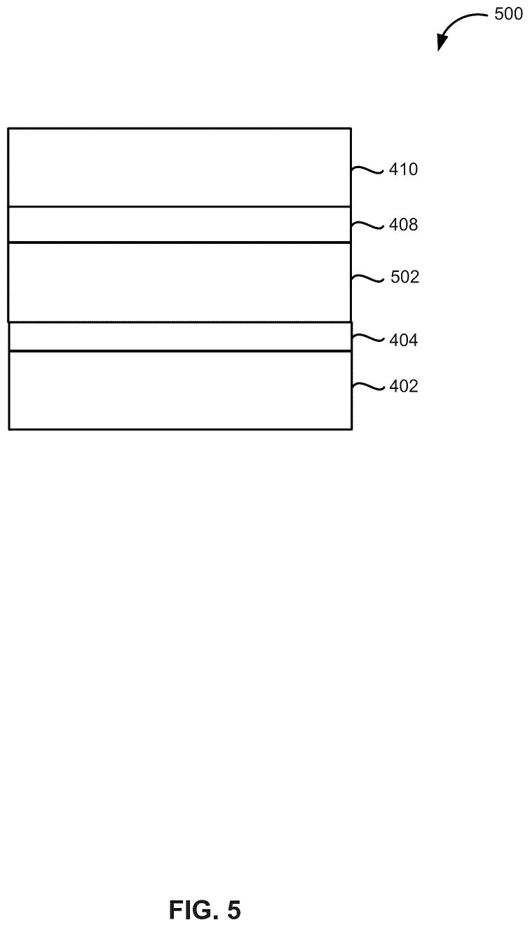

FIGS. 4 and 5 illustrate structures 400 and 500 formed in accordance with examples of the disclosure—e.g., using method 100. Structure 400 includes a substrate 402, an oxide layer 404 (e.g., an interlayer dielectric (e.g., oxide, such as silicon oxide)), a threshold voltage tuning layer 406, a high-k dielectric material layer 408, and a capping layer 410.

Substrate 402 can be as described above. Oxide layer 404 can be the same or similar to the oxide surface described above. Threshold voltage tuning layer 406 can be formed according to method 100—e.g., using one or more cycles 108, each cycle 108 including providing a treatment reactant and depositing threshold voltage tuning material. By way of examples, threshold voltage tuning layer 406 can include one or more of a lanthanum oxide, an aluminum oxide, gallium oxide, or zinc oxide. High-k dielectric material layer 408 can include, for example, hafnium oxide, zirconium oxide, hafnium zirconium oxide, or hafnium silicate. Capping layer 410 can be or include a metal (e.g., a transition metal) nitride, such as titanium nitride.

In the illustrated example, threshold voltage tuning layer 406 is formed overlying and in contact with oxide layer 404. This structure is referred to as a dipole first structure. In accordance with other examples of the disclosure, threshold voltage tuning layer 406 can be formed overlying high-k dielectric material layer 408. Such structures are referred to as dipole last structures.

Structure 500 is similar to structure 400, except structure 500 includes a threshold voltage tuning layer 502, rather than threshold voltage tuning layer 406. Threshold voltage tuning layer 502 can be similar to threshold voltage tuning layer 406, except threshold voltage tuning layer 502 is formed using two or more cycles 108. The other layers and substrate of structure 500 can be as described above in connection with structure 400. Similar to structure 500, structure 500 can be alternatively formed with layer 502 overlying layer 408.

As noted above, method 100 can also be used to form dipole middle structures, such as structure 702.

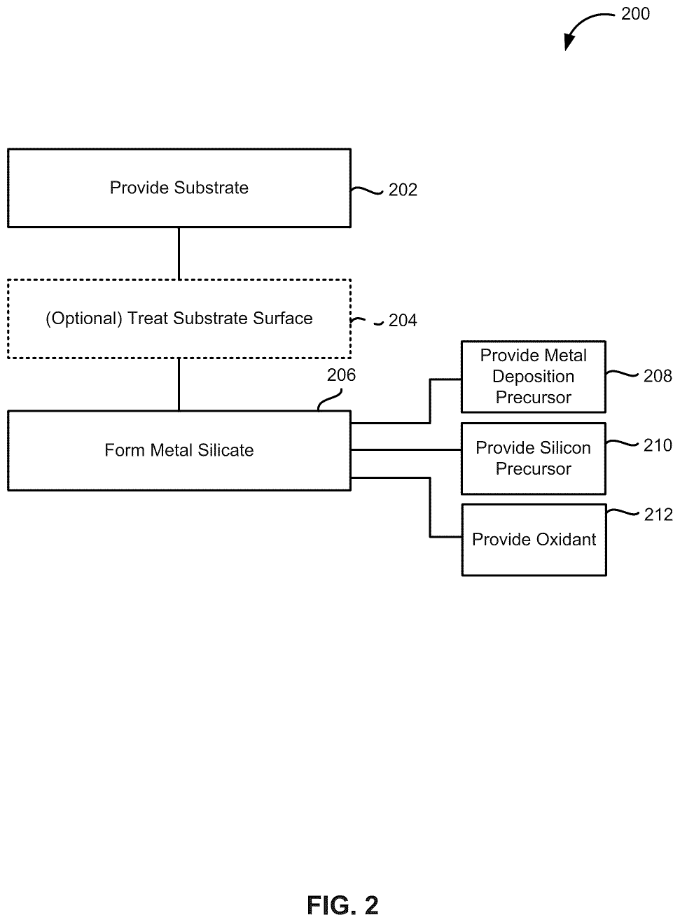

FIG. 2 illustrates another method 200 in accordance with additional examples of the disclosure. Method 200 may be particularly beneficial for the formation of p-dipole threshold voltage tuning layers.

Method 200 includes the steps of providing a substrate (step 202) and using a cyclical deposition process, depositing threshold voltage tuning material overlying the substrate surface (step 206). As illustrated, method 200 can optionally include a treatment step 204.

Step 202 includes providing a substrate comprising a substrate surface within a reaction chamber. Step 202 can be the same or similar to step 102 described above.

When or if included, step 204 can be the same or similar to step 104 described above.

During step 206, a metal silicate can be formed directly on the substrate surface, which can include a treated surface as described herein. As illustrated, step 205 can include providing a metal deposition precursor to the reaction chamber (step 208), providing a silicon precursor to the reaction chamber (step 210), and providing an oxidant to the reaction chamber (step 212). The threshold voltage tuning layer formed using method 200 can include one or more of silicon-doped niobium oxide, silicon-doped aluminum oxide, silicon-doped lanthanum oxide, silicon-doped yttrium oxide, silicon-doped scandium oxide, or silicon-doped lutetium oxide, or the like, which can be formed without an additional heating or annealing step.

The metal deposition precursor provided during step 208 may include a halogen and/or may be a carbon-free precursor. In some cases, the metal deposition precursor comprises heteroleptic and/or homoleptic molecules, such as molecules represented by M (a metal) in combination with RCp and/or AMD groups. In some embodiments, the metal deposition precursor is a rare earth metal precursor (such as lanthanum La, Ac,Y, Ce, Pr, Nd, Sm, Eu, Gd, Tb, Dy, Ho, Er, Tm, Yb or Lu precursor). The metal deposition precursor can comprise a bond between the rare earth metal and nitrogen or a bond between rare earth metal and carbon. In some embodiments, the rare earth metal precursor comprises a bidentate ligand bonded to lanthanum through two nitrogen atoms. In some embodiments, the rare earth metal in the rare earth metal precursor (e.g., lanthanum) has an oxidation state of +III. In some embodiments, the rare earth metal precursor has three organic ligands, such as ligands containing nitrogen or carbon. In some embodiments, the rare earth metal precursor (e.g., lanthanum) does not comprise silicon or germanium. In some embodiments, the metal deposition precursor comprises a metal atom bonded to a nitrogen atom and to a carbon atom.

In at least one embodiment, a metal deposition precursor may be one of the following: an amidinate based precursor, such as lanthanum formamidinate (La(FAMD)₃) or tris(N,N′-diisopropylacetamidinato)lanthanum (La(iPrAMD)₃); a diketonate precursor, such as (La(THD)₃); a Cp(cyclopentadienyl)-based precursor such as tris(isopropyl-cyclopentadienyl)lanthanum (La(iPrCp)₃); or an amido-based chemistry such as tris(bistrimethylsilylamido)-lanthanum (La[N(SiMe₃)₂]₃); or hybrid combinations of the above. In other embodiments, the metal deposition precursor may be a lanthanum or other rare earth metal precursor having a bond between nitrogen, such as a lanthanum amidinate, for example. The amidinate compounds may comprise delocalized electrons that result in the bond between the nitrogen and the lanthanum or rare earth metal. In other embodiments, the metal deposition precursor may be a lanthanum or other rare earth metal precursor having a bond with carbon, such as a lanthanum cyclopentadienyl, for example. This metal precursor may comprise delocalized electrons, which are considered to be compounds, in which the bond between the carbon and the lanthanum or rare earth forms. In other embodiments, the metal deposition precursor may be a lanthanum or other rare earth metal precursor having a bond with both nitrogen and carbon, such as a lanthanum amidinate and a lanthanum cyclopentadienyl compound, for example

By way of examples, the metal deposition precursor can be or include AlCl₃, Y(EtCp)₃, or the like.

The step of providing the silicon precursor 210 can include providing a carbon-free, halogen-containing silicon precursor. Exemplary precursors can include, for example, 1-6 silicon atoms. Each silicon atom can be bonded to H, Cl, Br, I and/or another silicon atom. The silicon precursor can include 0 to a maximum number of bonded halogen atoms, which can be the same or different. For example, the silicon precursor can be or include SiX₄, Si₂X₆, or Si₃X₈, or the like, wherein each X is independently H, Cl, Br, or I.

The oxidant provided during step 212 can be or include any oxidant noted above in connection with step 106.

In accordance with examples of the disclosure, during a (e.g., during one or more of each) deposition cycle comprising steps 208-212, step 210 may precede step 208 and step 212. This order of steps 208-212 is thought to facilitate desired growth rate of the metal silicate.

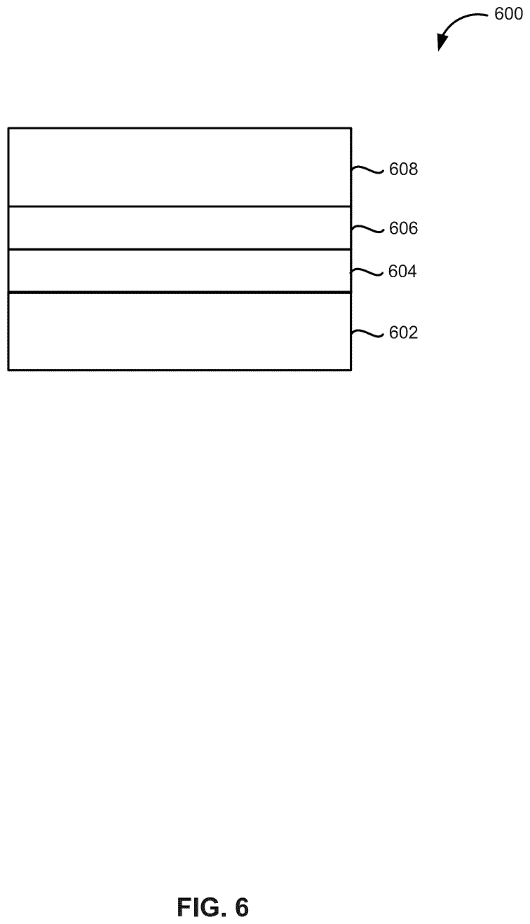

FIG. 6 illustrates a structure 600, which can be formed, at least in part, using method 200. Structure 600 includes a substrate 602, an oxide layer 604, a metal silicate layer 606, and a high-k dielectric layer 608.

Substrate 602, oxide layer 604, and high-k dielectric layer 608 can be as described above in connection with FIGS. 4 and 5. Metal silicate layer 606 can be formed as described above in connection with FIG. 2, without a post-deposition anneal.

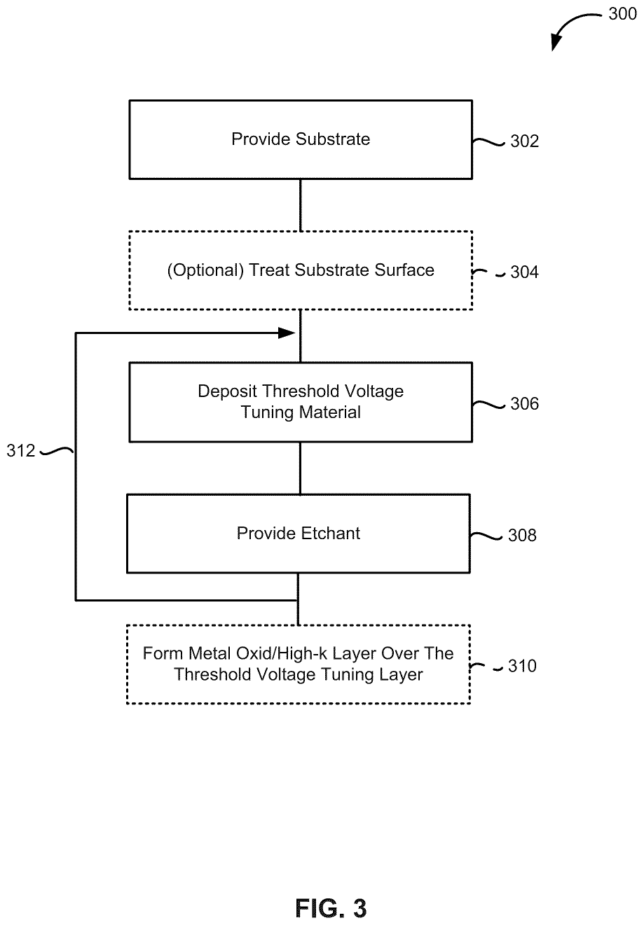

FIG. 3 illustrates yet another method 300 in accordance with examples of the disclosure. Method 300 includes providing a substrate (step 302), optionally treating a surface of the substrate (step 304), depositing threshold voltage tuning material overlying the substrate surface (step 306), providing an etchant (step 308), and optionally forming a metal oxide/high-k dielectric material (step 310).

Steps 302-306 can be the same or similar to steps 102-106 described above. However, as noted above, method 300 may, in some cases, not include a treatment step.

During step 308, an etchant can be introduced into the reaction chamber. The etchant can act as a nucleation promoter to homogenize nucleation of threshold voltage tuning material and/or to reduce growth rate of threshold voltage tuning material via a competitive etch process and/or etch a portion of the threshold voltage tuning material. When used during a deposition and etch cycle 312, the etchant can reduce a thickness of the threshold voltage tuning material, while retaining film closure, continuity, and relatively low roughness. Although separately illustrated, step 308 can form part of a cyclical deposition process for depositing the threshold voltage tuning material—e.g., a cyclical process that includes providing a threshold voltage tuning material precursor to the reaction chamber, providing a threshold voltage tuning material reactant to the reaction chamber, and providing the etchant to the reaction chamber.

The etchant can be a neutral compound that is capable of forming stable volatile complexes of a metal (e.g., aluminum or lanthanum) of the threshold voltage tuning material as the product of the etching reaction. Exemplary etchants can include a beta-diketonate compound, such as Hacac, Hthd, Hfac, or the like.

Step 310 can include any suitable method, such as a cyclical method of forming oxide/high-k dielectric material. By way of examples, the high-k dielectric layer can be or include hafnium oxide.

In accordance with yet additional embodiments of the disclosure, a device or portion thereof can be formed using a method and/or a structure as described herein. The device can include a substrate, a dielectric layer, and a threshold voltage tuning layer or metal silicate layer as described herein. The device can be or form part of, for example, a MOSFET, e.g., a pMOSFET or an nMOSFET. The device can be configured as a gate-all-around field effect transistor comprising a dipole layer or region that is formed according to a method as described herein.

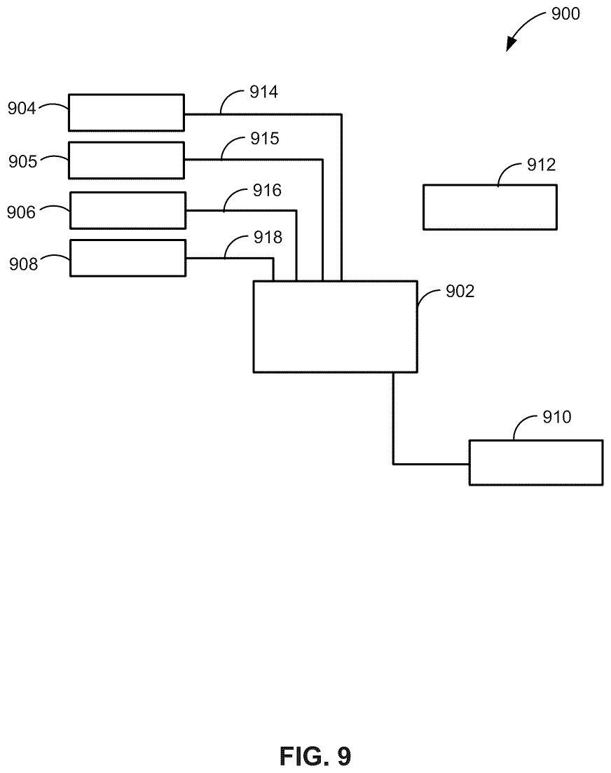

FIG. 9 illustrates a system 900 in accordance with yet additional exemplary embodiments of the disclosure. System 900 can be used to perform a method as described herein and/or form a structure or device portion as described herein.

In the illustrated example, system 900 includes one or more reaction chambers 902, a threshold voltage tuning material precursor source 904, a treatment reactant gas source 906, a threshold voltage tuning material reactant source 908, an exhaust 910, and a controller 912. Although not separately illustrated, system 900 can also include one or more purge gas sources.

Reaction chamber 902 can include any suitable reaction chamber, such as an ALD or CVD reaction chamber.

Threshold voltage tuning material precursor source 904 can include a vessel and one or more precursors as described herein-alone or mixed with one or more carrier (e.g., noble) gases. Treatment reactant gas source 906 can include a vessel and one or more treatment reactants as described herein-alone or mixed with one or more carrier gases. Threshold voltage tuning material reactant source 908 can include a vessel and one or more threshold voltage tuning material reactants as described herein-alone or mixed with one or more carrier gases. Purge gas sources can include one or more inert gases as described herein. Although illustrated with four gas sources 904-908, system 900 can include any suitable number of gas sources. Gas sources 904-908 can be coupled to reaction chamber 902 via lines 914-918, which can each include flow controllers, valves, heaters, and the like.

Exhaust 910 can include one or more vacuum pumps.

Controller 912 includes electronic circuitry and software to selectively operate valves, manifolds, heaters, pumps and other components included in the system 900. Such circuitry and components operate to introduce precursors, reactants, and purge gases from the respective sources 904-908. Controller 912 can control timing of gas pulse sequences, temperature of the substrate and/or reaction chamber, pressure within the reaction chamber, and various other operations to provide proper operation of the system 900. Controller 912 can include control software to electrically or pneumatically control valves to control flow of precursors, reactants and purge gases into and out of the reaction chamber 902. Controller 912 can include modules, such as a software or hardware component, e.g., a FPGA or ASIC, which performs certain tasks. A module can advantageously be configured to reside on the addressable storage medium of the control system and be configured to execute one or more processes.

Other configurations of system 900 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber 902. Further, as a schematic representation of a system, many components have been omitted for simplicity of illustration, and such components may include, for example, various valves, manifolds, purifiers, heaters, containers, vents, and/or bypasses.

During operation of reactor system 900, substrates, such as semiconductor wafers (not illustrated), are transferred from, e.g., a substrate handling system to reaction chamber 902. Once substrate(s) are transferred to reaction chamber 902, one or more gases from gas sources 904-908, such as precursors, reactants, carrier gases, and/or purge gases, are introduced into reaction chamber 902.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of forming a structure comprising a threshold voltage tuning layer, the method comprising:
providing a substrate comprising a substrate surface within a reaction chamber;
providing a treatment reactant comprising a metal treatment precursor to the reaction chamber to form a treated surface on the substrate surface; and
depositing threshold voltage tuning material overlying the treated surface, wherein the treatment reactant inhibits deposition of the threshold voltage tuning material.

2. The method of claim 1, wherein the metal treatment precursor comprises a metal selected from one or more of hafnium, zirconium, or aluminum.

3. The method of claim 1, wherein the metal treatment precursor comprises one or more hafnium chloride (HfCl₄), tetrakis(ethylmethylamido)hafnium(TEMAHf), bis(methylcyclopentadienyl) methylmethoxy Hf, zirconium chloride (ZrCl₄), tetrakis(ethylmethylamido)zirconium(TEMAZr), bis(methylcyclopentadienyl) methylmethoxy Zr, or tris (dimethylamino) (cyclopentadienyl)zirconium.

4. The method of claim 2, wherein the substrate surface comprises the metal.

5. The method of claim 1, wherein the step of depositing threshold voltage tuning material comprises a cyclical deposition process comprising:
providing a threshold voltage tuning material precursor to the reaction chamber; and
providing a threshold voltage tuning material reactant to the reaction chamber.

6. The method of claim 5, wherein the threshold voltage tuning material reactant removes a ligand of the treatment reactant on the treated surface.

7. A method of forming a structure comprising a threshold voltage tuning layer, the method comprising:
providing a substrate comprising a substrate surface within a reaction chamber;
providing a treatment reactant comprising a carbon-containing treatment precursor to the reaction chamber to form a treated surface on the substrate surface; and
depositing threshold voltage tuning material overlying the treated surface.

8. The method of claim 7, wherein the carbon-containing treatment precursor comprises one or more of an aminosilane, an alkyl amine, and formamidine.

9. The method of claim 7, wherein the carbon-containing treatment precursor comprises one or more of an acyl halide or an alkyl diacyl halide.

10. The method of claim 7, wherein the carbon-containing treatment precursor comprises a carboxylic acid anhydride.

11. The method of claim 7, wherein the carbon-containing treatment precursor comprises an alcohol.

12. The method of claim 7, further comprising repeating the steps of providing the treatment reactant to the reaction chamber and depositing the threshold voltage tuning material overlying the treated surface to form the threshold voltage tuning layer.

13. A method of forming a structure comprising a threshold voltage tuning layer, the method comprising:
providing a substrate comprising a substrate surface within a reaction chamber; and
using a cyclical deposition process, depositing threshold voltage tuning material overlying the substrate surface, wherein the cyclical deposition process comprises:
providing a metal deposition precursor to the reaction chamber;
providing a silicon precursor to the reaction chamber; and
providing an oxidant to the reaction chamber.

14. The method of claim 13, wherein the step of providing the metal deposition precursor comprises providing a carbon-free, halogen-containing metal precursor.

15. The method of claim 14, wherein the step of providing the silicon precursor comprises providing a carbon-free, halogen-containing silicon precursor.

16. The method of claim 14, wherein the threshold voltage tuning layer comprises one or more of silicon-doped niobium oxide and silicon-doped aluminum oxide.

17. A method of forming a structure comprising a threshold voltage tuning layer, the method comprising:
providing a substrate comprising a substrate surface within a reaction chamber;
depositing threshold voltage tuning material overlying the substrate surface;
providing an etchant to the reaction chamber to form the threshold voltage tuning layer; and
forming a metal oxide layer over the threshold voltage tuning layer.

18. The method of claim 17, wherein the etchant comprises a beta-diketonate compound.

19. The method of claim 17, further comprising a step of treating the surface of the substrate with a treatment reactant to inhibit growth of the threshold voltage tuning material.

20. The method of claim 17, wherein the threshold voltage tuning layer comprises one or more of a lanthanum oxide, an aluminum oxide, a gallium oxide, a zinc oxide, a silicon-doped niobium oxide, a silicon-doped aluminum oxide, a silicon-doped lanthanum oxide, a silicon-doped yttrium oxide, a silicon-doped scandium oxide, or a silicon-doped lutetium oxide.
